(19) United States
(12) Patent Application Publication
(10) Pub. No.: US 2010/0006136 A1
(43) Pub. Date: Jan. 14, 2010

(54) MULTIJUNCTION HIGH EFFICIENCY PHOTOVOLTAIC DEVICE AND METHODS OF MAKING THE SAME

(75) Inventor: Joshua M. O. Zide, Newark, DE (US)

Correspondence Address: RATNERPRESTIA, P.O. BOX 1596, WILMINGTON, DE, 19899, US

(73) Assignee: University of Delaware, Newark, DE (US)

(21) Appl. No.: 12/499,172

(22) Filed: Jul. 8, 2009

Related U.S. Application Data
(60) Provisional application No. 61/078,891, filed on Jul. 8, 2008.

(51) Int. Cl. H01L 31/042; H01L 31/18

(52) U.S. Cl. 136/244; 438/73; 257/E21.085

(57) ABSTRACT

Photovoltaic devices and methods of making photovoltaic devices are provided. The photovoltaic device comprises a plurality of solar cells electrically coupled to each other. The plurality of solar cells are formed of respective semiconductor material having different band gaps. Each solar cell includes a plurality of sub-junctions having a respective plurality of p-n junctions and at least one tunnel junction located between juxtaposed sub-junctions of the plurality of sub-junctions.

### CROSS-REFERENCE TO RELATED APPLICATIONS

This application is related to and claims the benefit of U.S. Provisional Application No. 61/078,891 entitled MANY-JUNCTION HIGH EFFICIENCY SOLAR CELL filed on Jul. 8, 2008, the contents of which are incorporated herein by reference.

### FIELD OF THE INVENTION

The present invention relates to photovoltaic devices. More particularly, the present invention relates to multijunction solar photovoltaic devices and methods of making the same.

### BACKGROUND OF THE INVENTION

Solar photovoltaic devices, i.e. solar cells, are devices capable of converting solar radiation into electrical energy. Solar cells typically include a p-type doped semiconductor layer adjacent to an n-type doped semiconductor layer, referred to as a p-n junction. In general, solar radiation impinges on the solar cell and is absorbed by an active region of the p-n junction, typically according to the photovoltaic-effect, to generate electricity. It is also known to improve energy conversion efficiency of photovoltaic devices by vertically stacking and interconnecting two or more solar cells, such as with tunnel junctions, to form a multijunction solar cell.

### SUMMARY OF THE INVENTION

Embodiments of the present invention include a photovoltaic device including a plurality of solar cells electrically coupled to each other. The plurality of solar cells are formed of respective semiconductor material having different band gaps. Each solar cell includes a plurality of sub-junctions having a respective plurality of p-n junctions and at least one tunnel junction located between juxtaposed sub-junctions of the plurality of sub-junctions.

The present invention is also embodied in a photovoltaic apparatus including a top electrode formed of a top electrode material, a bottom electrode formed of a bottom electrode material and a photovoltaic device coupled between the top electrode and the bottom electrode. The photovoltaic device includes a plurality of solar cells electrically coupled to each other. The plurality of solar cells are formed of respective semiconductor material having different band gaps. Each solar cell includes a plurality of sub-junctions having a respective plurality of p-n junctions and at least one tunnel junction located between juxtaposed sub-junctions of the plurality of sub-junctions.

The present invention is also embodied in a method of forming a photovoltaic device including forming a plurality of solar cells of respective semiconductor material having different band gaps such that the plurality of solar cells are electrically coupled to each other. Each solar cell is formed by forming a plurality of sub-junctions having respective p-n junctions and forming at least one tunnel junction. The at least one tunnel junction located between juxtaposed sub-junctions of the plurality of sub-junctions.

### BRIEF DESCRIPTION OF THE DRAWINGS

The invention may be understood from the following detailed description when read in connection with the accompanying drawing. It is emphasized, according to common practice, that various features of the drawing may not be drawn to scale. On the contrary, the dimensions of the various features may be arbitrarily expanded or reduced for clarity. Moreover, in the drawing, common numerical references are used to represent like features. Included in the drawing are the following figures:

FIG. 1 is a cross-sectional diagram of a conventional multijunction solar photovoltaic device;

FIG. 2 is a cross-sectional diagram of a multifunction photovoltaic device according to an embodiment of the present invention;

FIG. 3A is a cross-sectional diagram of a first solar cell shown in FIG. 2;

FIG. 3B is a cross-sectional diagram of a second solar cell shown in FIG. 2;

FIG. 4 is a cross-sectional diagram of a photovoltaic apparatus according to an embodiment of the present invention;

FIG. 5 is a cross-sectional diagram of a photovoltaic device according to another embodiment of the present invention; and

FIG. 6 is a flowchart of exemplary steps for forming a photovoltaic apparatus according to embodiments of the present invention.

### DETAILED DESCRIPTION OF THE INVENTION

Aspects of the present invention include multijunction solar photovoltaic devices (also referred to herein as photovoltaic devices) and methods of making the same. The photovoltaic device includes a plurality of solar cells coupled to each other via respective tunnel junctions. Exemplary solar cells of the present invention include a plurality of sub-junctions and at least one tunnel junction located between juxtaposed sub-junctions of the plurality of sub-junctions. Each sub-junction includes a p-type semiconductor layer and an n-type semiconductor layer, to form a p-n junction. Each solar cell may be formed from a material having a different band gap. Exemplary photovoltaic devices are configured to be operated at temperatures above room temperature (defined herein as being about 20° C.).

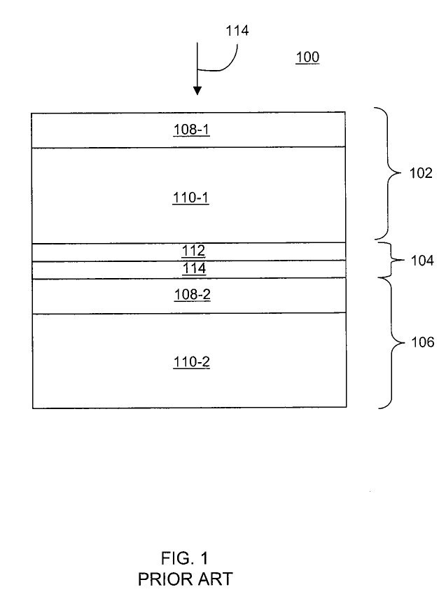

Referring to FIG. 1, a cross-sectional diagram of a conventional multijunction photovoltaic device 100 is shown. Device 100 includes first solar cell 102 and second solar cell 106 interconnected to each other via tunnel junction 104. Device 100 receives incident solar radiation 112 on a top surface of solar cell 102 and converts incident radiation 112 to electrical energy.

First solar cell 102 includes p-type semiconductor layer 108-1 and n-type semiconductor layer 110-1, which form a p-n junction. Similarly, second solar cell 106 includes p-type semiconductor layer 108-2 and n-type semiconductor layer 110-2 to form a respective p-n junction. As one example, first solar cell 102 may be formed from gallium indium phosphide (GaInP) and second solar cell 106 may be formed from gallium arsenide (GaAs).

In general, the semiconductor material used for first and second solar cells 102, 106 is selected such that the respective band gap decreases with increasing distance from the top surface of device 100 (i.e., a depth relative to the top surface of first solar cell 102). Accordingly, first solar cell 102 typically is formed from semiconductor material having a wider band gap compared to second solar cell 106. In other words, second solar cell 106 is formed from semiconductor material having a narrow band gap as compared to first solar cell 102. By selecting semiconductor material with narrower band gaps with increasing depth, multijunction solar cells may achieve higher efficiencies over single-junction cells. For example, the wider band gap top solar cell 102 may collecting higher-energy photons at a larger voltage, whereas the narrower band gap second cell 106 may collect lower-energy photons (which are not absorbed in the first solar cell 102).

Tunnel junction 104 includes n⁺-type layer 112 and p⁺-type layer 114 and provides an interface between heavily doped n⁺ and p⁺ layers. The heavy doping results in a short depletion width, creating a thin barrier for tunneling, such that electrons in a conduction band of n⁺-type layer 112 can tunnel into states in a valence band of p⁺-type layer 114. In general, first and second solar cells 102, 106 include respective semiconductor p-n junctions in which absorbed photons produce carriers which are separated across the depletion region, resulting in a photovoltage across the respective solar cell. The photovoltage of a multijunction photovoltaic device, such as device 100, is typically the sum of the photovoltages of the individual solar cells 102, 106.

Multijunction photovoltaic devices, such as device 100, are known for generating a high efficiency solar energy conversion. In principle, a multijunction photovoltaic device with an infinite number of junctions may have greater than 70% efficiency. In practice, however, multijunction cells are typically formed with three junctions, and have efficiencies of about 40%. In addition, conventional multijunction photovoltaic devices are typically optimized for room temperature operation, e.g., about 20° C.

Multijunction solar cells are typically produced by epitaxial growth techniques, with solar concentration being used to reduce the device area and, thus, the cost. The increased concentration, resulting from using optics to focus light from a wider area onto a smaller device, may result in an increase of temperature for operating the conventional multijunction photovoltaic device. The increase in temperature also tends to decrease the energy conversion efficiency. In general, all photovoltaic devices have limited efficiencies, where any remaining solar radiation that is not converted to electrical energy is typically present as heat.

The decrease in energy conversion efficiency due to increased operation temperature may be caused by: 1) a reduced band gap of the semiconductor material at higher temperatures and 2) a decreased minority carrier diffusion length. Multijunction photovoltaic devices of the present invention can be designed to operate at temperatures greater than room temperature, and to compensate for these two causes of decreased efficiency, as described further below.

With respect to the reduced band gap of the semiconductors material, it is typically difficult to produce ideal band gaps for multijunction photovoltaic devices. For example, for a conventional two-junction photovoltaic device, such as device 100, the ideal band gap of second solar cell 106 is about 1 eV. Generally, however, second solar cell 106 is formed from GaAs, having a band gap of about 1.4 eV. At room temperature, the band gap of 1.4 eV (for second solar cell 106) results in a loss in efficiency. For example, a theoretical maximum for a two-junction cell is nearly about 50%, whereas in practice a maximum of about 33% efficiency has been reported.

According to the present invention, by increasing the temperature of the photovoltaic device, it is possible to reduce the band gap of each of the solar cells included in the device. As an example, a two-junction photovoltaic device including a GaAs bottom solar cell and a GaAlInP top solar cell is described (where the top solar cell receives the incident solar radiation). At elevated temperatures (e.g. 150° C.), the band gap of GaAs is reduced to approximately 1.2 eV (as compared to the ideal band gap is 1 eV), whereas the GaAlInP composition can be selected to achieve a desired band gap for maximum efficiency, which is approximately 1.7 eV. A first solar cell 102 having a band gap of approximately 1.7 eV and a second solar cell 106 having a band gap of approximately 1.2 eV results in an efficiency of approximately 39%. Accordingly, photovoltaic devices of the present invention may increase the operating temperature to reduce the band gap of each solar cell to approach ideal band gaps for two or more junction photovoltaic devices.

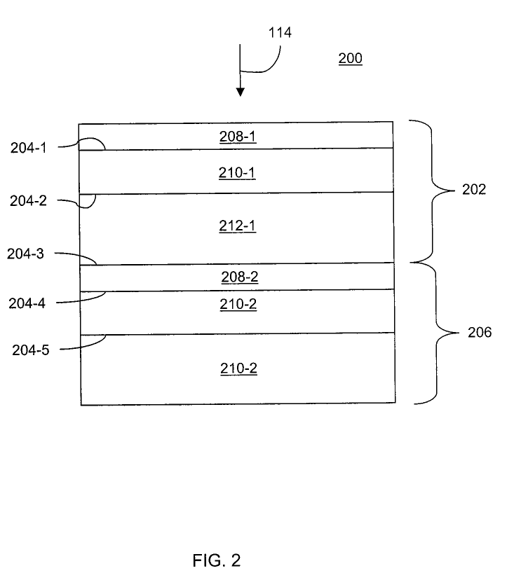

As described above, a second reason for a decrease in efficiency is a decrease minority carrier diffusion length with an increase in temperature. In general, a thickness of a junction in a multijunction photovoltaic device is desirably sufficiently thick to absorb substantially all of the photons which can be absorbed by the band gap. However, the thickness of a p-n junction is typically less than the minority carrier diffusion length, in order to prevent a recombination of the electron-hole pairs. According to the present invention, a material having a shorter minority carrier length diffusion may be formed by splitting each junction into thinner sub-junctions which are interconnected with tunnel junctions, as described below with respect to FIGS. 2-5. As a result, each sub-junction (which includes a p-type layer and an n-type layer and forms a p-n junction) may be formed thinner than the minority carrier diffusion length. Accordingly, each solar cell of the present invention includes a plurality of sub-junctions which form a respective plurality of p-n junctions, with tunnel junctions located between juxtaposed sub-junctions.

Referring to FIG. 2, a cross-sectional diagram of an exemplary multijunction photovoltaic device 200 is shown. Device 200 includes first solar cell 202 and second solar cell 206 interconnected by tunnel junction 204-3. Device 200 is configured to receive solar radiation 114 from a top surface of first solar cell 202. Radiation not absorbed by first solar cell 202 passes from a bottom surface of first solar cell 202 to a top surface of second solar cell 206.

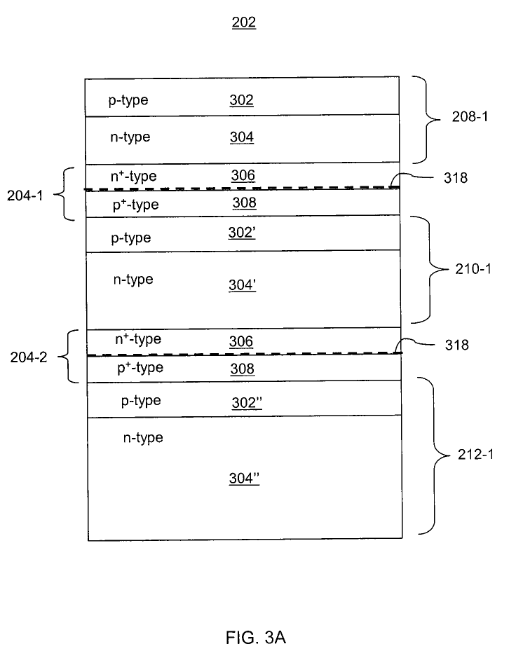

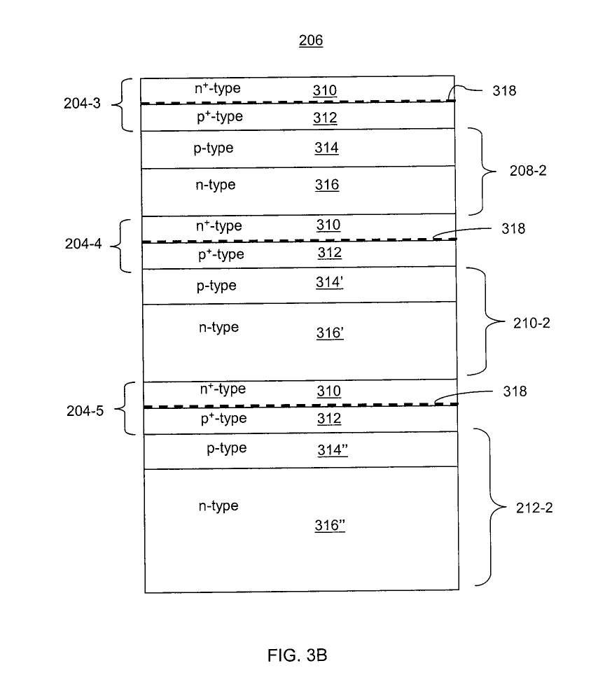

Each solar cell 202, 206 includes a plurality of sub-junctions 208, 210, 212. Each sub-junction 208, 210, 212 forms a p-n junction, as described further with respect to FIGS. 3A and 3B. Sub-junctions 208-1, 210-1 and 212-1 of first solar cell 202 are interconnected by respective tunnel junctions 204-1, 204-2. Similarly, sub-junctions 208-2, 210-2 and 212-2 of second solar cell 206 are interconnected by respective tunnel junctions 204-4, 204-5. Accordingly, a tunnel junction 204 is position between juxtaposed sub-junctions, for example, between sub-junction 208-1 and 210-1.

In general, each solar cell 204, 206 may be considered a collective p-n junction, formed from the plurality of sub-junctions 208, 210, 212. Although FIG. 2 illustrates that each solar cell 202, 206 includes three sub-junctions 208, 210, 212, it is to be understood that solar cells 202, 206 may include two or more sub-junctions and that a suitable number of sub-junctions may be selected such that the sub-junctions have a thickness that is thinner than a desired minority carrier diffusion length for the collective p-n junction of solar cells 202, 206, as described above.

For maximum efficiency, a total thickness of each solar cell 202, 206, is desirably selected to absorb substantially all photons with energy large enough to be absorbed by the respective solar cell. Each sub-junction 208, 210, 212 is desirably formed thinner than the minority carrier diffusion length at the desired temperature. For maximum efficiency, it may be desirable for all sub-junctions 208, 210, 212 within photovoltaic device 200 to be substantially current matched. By providing a current matched structure, a same number of photons may be absorbed in each sub-junction 208, 210, 212.

In an exemplary embodiment, first solar cell 202 is formed from GaInP and second solar cell 206 is formed from GaAs. In general, first solar cell 202 is formed from a semiconductor material having a wider band gap as compared to second solar cell 206. It is to be understood that solar cells 202, 206 may be formed from any suitable semiconductor material, including, but not limited to GaInP, GaAlInP, GaAs, germanium (Ge), indium gallium arsenide (InGaAs), silicon (Si), indium gallium aluminum arsenide (InGaAlAs), and aluminum gallium arsenide (AlGaAs).

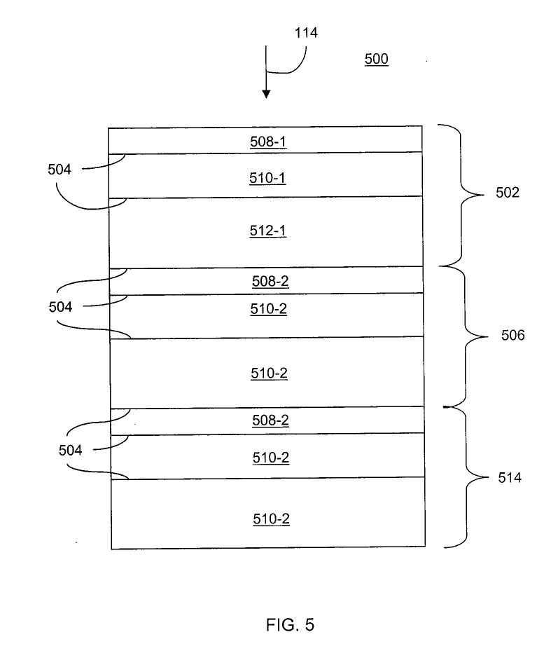

Furthermore, although two solar cells 202, 206 are shown in FIG. 2, it is to be understood that an exemplary photovoltaic device may include more than two solar cells. Referring to FIG. 5, an exemplary photovoltaic device 500 including three solar cells 502, 506 and 514 is shown. Solar cells 502, 506, 514 are interconnected via tunnel junctions 504. Photovoltaic device 500 receives incident radiation 114 on a top surface of first solar cell 502 (i.e., a top surface of device 500), with unabsorbed radiation being passed to subsequent solar cells 506 and 514. Each solar cell 502, 506, 514 includes respective sub-junctions 508, 510, 512 interconnected via tunnel junctions 504.

In an exemplary embodiment, first solar cell 502 is formed from GaInP, second solar cell 506 is formed from GaAs and third solar cell 514 is formed from Ge. In general, solar cells 502, 506, 514 are formed from materials such that the respective band gap decreases with increasing distance from the top surface of device 500.

Referring next to FIGS. 3A and 3B, cross-sectional diagrams of respective first solar cell 202 and second solar cell 206 are shown. In particular, FIG. 3A is a cross-sectional diagram illustrating an arrangement of sub-junctions 208-1, 210-1 and 212-1 with respect to tunnel junctions 204-1 and 204-2 of first solar cell 202; and FIG. 3B is a cross-sectional diagram illustrating an arrangement of sub-junctions 208-2, 210-2, 212-2 with respect to tunnel junctions 204-3, 204-4 and 204-5.

Sub-junction 208-1 is formed from p-type layer 302 and n-type layer 304, thus forming a p-n junction. P-type layer 302 and n-type layer 304 is similar to p-type layer 314 and n-type layer 316, respectively, except that layers 302, 304 are formed from a material with a different band gap. Sub-junctions 208, 210 and 212 are formed to have an increasing thickness with distance away from a top surface of respective first solar cell 202 and second solar cell 206.

In FIG. 3A, sub-junctions 208, 210, 212 are formed from p-type layers 302, 302′, 302″ and n-type layers 304, 304′, 304″, respectively. Layers 302′ and 302″ are similar to layer 302, except that layers 302′ and 302″ may have an increasing thickness with increasing distance from a top surface of solar cell 202. Layers 304′ and 304″ are similar to layer 304, except that layers 304′ and 304″ may have an increasing thickness with increasing distance from a top surface of first solar cell 202. In FIG. 3B, sub-junctions 208, 210, 212 are similarly formed from p-type layers 314, 314′, 314″ and n-type layers 316, 316′, 316″. Layers 314′ and 314″ are similar to layer 314, except that layers 314′ and 314″ may have an increasing thickness with increasing distance from a top surface of solar cell 206. Layers 316′ and 316″ are similar to layer 316, except that layers 316′ and 316″ may have an increasing thickness with increasing distance from a top surface of second solar cell 206. In general, the thickness of each sub-junction may increase with depth as the number of photons are reduced by the number of previously absorbed photons in higher layers of the respective solar cell, with the thicknesses being a function of the minority carrier diffusion length and the absorption coefficient. In general, thicknesses of the sub-junctions within respective solar cells 202, 206 may increase with depth exponentially, in accordance with the exponential absorption of solar radiation with thickness. A total thickness of each solar cell 202, 206 may be a few micrometers or less. Suitable thickness will be understood by one of skill in the art from the description herein.

Tunnel junctions 204-1, 204-2, 204-3, 204-4, 204-5 are formed from respective n⁺-type layers 306, 310 and p⁺-type layers 308, 312. Tunnel junction 204-1, 204-2 may be formed from a same material as first solar cell 202, with increased doping concentrations. Similarly, tunnel junction 204-3, 204-4, 204-5 may be formed from a same material as solar cell 206 with an increased doping concentration. In an exemplary embodiment, doping concentrations for n⁺-type layers 306, 310 include concentrations of about 5×10¹⁸ cm⁻³ or higher and doping concentrations for p⁺-type layers 308, 312 include concentrations of about 1×10²⁰ cm⁻³ or higher. Doping concentrations for sub-junctions 208, 210, 212 may be, for example, between about 1×10¹⁶ cm⁻³ to about 1×10¹⁸ cm⁻³.

Tunnel junction 204 may also include metallic erbium arsenide (ErAs) nanoparticles between n⁺-type layer 306 (310) and p⁺-type layers 308 (312), generally depicted as ErAs monolayer 318. An example tunnel junction which uses metallic ErAs nanoparticles is described in U.S. Patent Application Publication No. 2008/0001127 to Zide et al., which is incorporated herein by reference.

As described above, exemplary photovoltaic device 200 includes a plurality of sub-junctions for each solar cell so that each sub-junction may be thinner than the minority diffusion length at a desired temperature. In addition, photovoltaic device 200 may be optimized for operation at temperatures above room temperature. As described above, one heat source for typical multijunction photovoltaic devices includes solar radiation that passes through the device which is not converted to electrical energy. This heat source may be used as an advantage in photovoltaic device 200, by reducing the band gap of the semiconductor materials toward an ideal band gap.

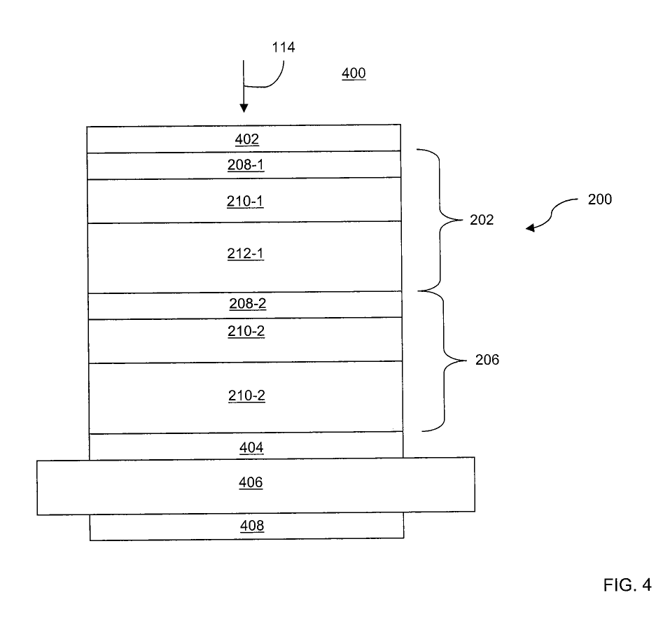

Referring to FIG. 4, a cross-sectional diagram of an exemplary photovoltaic system is shown. Photovoltaic apparatus 400 includes top electrode 402, photovoltaic device 200, bottom electrode 404 and substrate 408. At least one of top electrode 402 bottom electrode 404 is formed of an electrode material that is transparent to at least one desired wavelength of solar radiation, such as any transparent conduction oxide (TCO). Alternatively, top and/or bottom electrodes 402, 404 may be formed from any suitable metal electrode material provided on photovoltaic device 200 in a grid-formation, such that incident radiation 114 of the desired wavelength is capable of being passed into photovoltaic device 200. Substrate 408 may also be semi-insulating. Substrate 408 may be formed of material including, but not limited to, GaAs, Si, Ge or indium phosphide (InP).

Apparatus 400 may optionally include thermoelectric device 406. Thermoelectric device 406 may be used as an additional heat source, and may provide additional energy (e.g., a few percentage of the incident radiation), such that the additional energy may be added to the energy conversion efficiency of photovoltaic device 200. The additional energy may be about 3-5% with a conventional thermoelectric device to as much as about 20% *(1-cell_efficiency) for a theoretical thermoelectric device, where the cell_efficiency refers to the energy conversion efficiency of photovoltaic device 200. In general, the amount of additional energy (i.e., as heat) which is available for conversion using thermoelectric device 406 includes the incident solar energy which is not converted to electricity by photovoltaic device 200. In an exemplary embodiment, photovoltaic device 200 is operated at a temperature greater than about 20° C., more preferably greater than about 20° C. and less than about 150° C. Thermoelectric device 406 may include active circuitry (not shown) to operate photovoltaic device 200 at a substantially constant temperature (which may fluctuate due to the heat source of photovoltaic device 200 itself). Suitable thermoelectric devices capable of controlling a temperature between room temperature and about 150° C. will be understood by one of skill in the art. One example of thermoelectric device 406 includes a conventional thermoelectric power generator manufactured by BSST Incorporated of Irwindale, Calif., USA. An example of active circuitry may include active circuitry to configure thermoelectric device 406 to function as a power generator and as a Peltier cooler to stabilize the temperature.

Thermoelectric device 406 may be mechanically bonded to bottom electrode 404 with any suitable thermally conducted adhesive. Sub-junction layers 208, 210, 212 and tunnel junctions 204 may be grown using any known epitaxial growth techniques. It is to be understood that the sub-junction layers and tunnel junctions may also be formed using any suitable semiconductor deposition technique including, but not limited to, sputtering, thermal evaporation, and chemical vapor deposition.

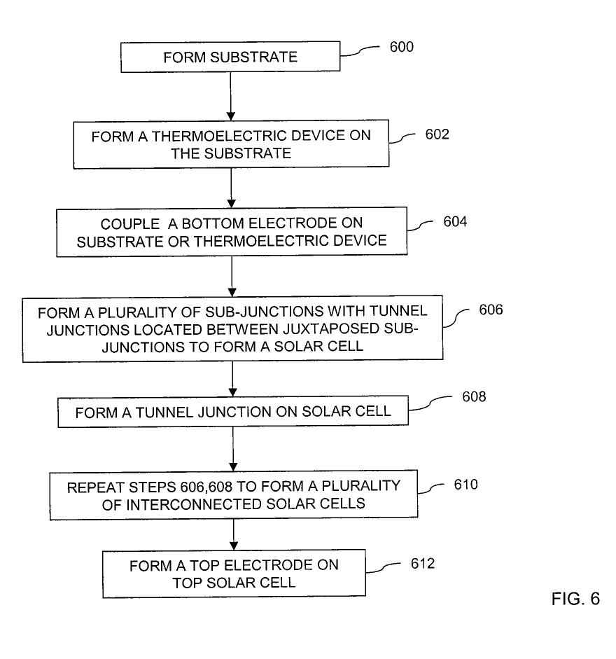

Referring next to FIGS. 4 and 6, flowchart of exemplary steps for forming a photovoltaic apparatus is shown. At step 600, a substrate 408 is formed. At optional step 602, a thermoelectric device 406 is formed on substrate 408. At step 604, a bottom electrode 404 is coupled to substrate 408 or, optionally, to thermoelectric device 406. At step 606, a plurality of sub-junctions (for example, sub-junctions 208-2, 210-2, 212-2) are formed with tunnel junctions 204 located between juxtaposed sub-junctions to form a solar cell, such as solar cell 206. Solar cell 206 is also coupled to bottom electrode 404.

At step 608, a tunnel junction 204 is formed on the solar cell, such as solar cell 206. At step 610, at least step 606 is repeated to form solar cell 202 interconnected to solar cell 206. Steps 608 and 606 may be additionally repeated depending on the number of interconnected solar cells desired to form the photovoltaic device. At step 612, a top electrode 402 is formed on a top solar cell, for example solar cell 202.

The present invention relates to high efficiency conversion of solar energy to electrical energy. The need for high efficiency concentrated solar cells is well established. The solar photovoltaic device of the present invention may better achieve this goal as compared with conventional technologies. Although a photovoltaic device is described above for solar energy conversion, other semiconductor devices may be formed using the concepts outlined herein where minority carrier diffusion length is a problem. Some example devices include vertical cavity surface emitting lasers (VCSELs) and bipolar transistors. For example, VCSELs may be fabricated with an active-region structure similar to the exemplary multijunction photovoltaic device. In general, VCSELs and bipolar transistors may be formed with multiple-active regions, as described above. The VCEL and bipolar transistor device structures may be grown by any epitaxial technique.

Examplary solar photovoltaic devices may provide a higher efficiency than existing solar cell technologies. One difference is in the use of sub-junctions (with the same band gap) to reduce the negative effects of short minority carrier diffusion lengths, to enable high-temperature operation of the cell (i.e., above room temperature). This may reduce a need for effective heatsinking and may allow for thermoelectric co-generation, which may result in a modest additional increase in efficiency.

The use of sub-junctions to reduce the junction thickness may be applicable to other materials in which short minority carrier lifetime is an impediment to device performance. These materials may be used in multifunction solar cells operating at any desirable temperature.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A photovoltaic device comprising:
a plurality of solar cells electrically coupled to each other, the plurality of solar cells formed of respective semiconductor material having different band gaps, each solar cell including:
a plurality of sub-junctions having a respective plurality of p-n junctions, and
at least one tunnel junction located between juxtaposed sub-junctions of the plurality of sub-junctions.

2. The photovoltaic device according to claim 1, wherein the photovoltaic device is configured to operate at a predetermined temperature above about 20° C.

3. The photovoltaic device according to claim 2, wherein the predetermined temperature is less than about 150° C.

4. The photovoltaic device according to claim 1, wherein the semiconductor material includes at least one of gallium indium phosphide (GaInP), gallium aluminum indium phosphide (GaAlInP), gallium arsenide (GaAs), indium gallium arsenide (InGaAs), silicon (Si), indium gallium aluminum arsenide (InGaAlAs), aluminum gallium arsenide (AlGaAs) or germanium (Ge).

5. The photovoltaic device according to claim 1, wherein the photovoltaic device includes a surface configured to receive radiation, the respective semiconductor material being selected for each solar cell such that the corresponding band gap decreases with increasing distance from the surface.

6. The photovoltaic device according to claim 1, wherein each solar cell includes a first surface configured to receive radiation and a second surface configured to pass the received radiation, the corresponding plurality of sub-junctions formed with increasing thickness from the first surface to the second surface.

7. The photovoltaic device according to claim 1, wherein each sub-junction includes first and second layers of the corresponding semiconductor material, the first and second layers having opposite doping types to form the respective p-n junction.

8. The photovoltaic device according to claim 1, wherein each tunnel junction includes first and second layers of the corresponding semiconductor material, the first and second layers having opposite doping types to form the respective tunnel junction.

9. The photovoltaic device according to claim 8, wherein each tunnel junction further includes an erbium arsenide (ErAs) monolayer between the first and second layers.

10. The photovoltaic device according to claim 1, wherein the plurality of sub-junctions in each of the solar cells are current matched.

11. The photovoltaic device according to claim 1, wherein the plurality of solar cells are electrically coupled to each other via respective further tunnel junctions.

12. A photovoltaic apparatus comprising:
a top electrode formed of a top electrode material;
a bottom electrode formed of a bottom electrode material; and
a photovoltaic device, coupled between the top electrode and the bottom electrode, comprising a plurality of solar cells electrically coupled to each other, the plurality of solar cells formed of respective semiconductor material having different band gaps, each solar cell including:
a plurality of sub-junctions having a respective plurality of p-n junctions, and
at least one tunnel junction located between juxtaposed sub-junctions of the plurality of sub-junctions.

13. The photovoltaic apparatus according to claim 12, wherein at least one of the top electrode material or the bottom electrode material is substantially transmissive to solar radiation have a predetermined wavelength.

14. The photovoltaic apparatus according to claim 12, further comprising a thermoelectric device coupled to the top electrode or the bottom electrode and configured to maintain the photovoltaic device at a predetermined temperature.

15. The photovoltaic apparatus according to claim 14, wherein the thermoelectric device includes circuitry configured to maintain the photovoltaic device at the predetermined temperature.

16. The photovoltaic apparatus according to claim 14, wherein the predetermined temperature is greater than about 20° C. and less than about 150° C.

17. A method of forming a photovoltaic device comprising:
forming a plurality of solar cells of respective semiconductor material having different band gaps such that the plurality of solar cells are electrically coupled to each other, each solar cell being formed by:
forming a plurality of sub-junctions having respective p-n junctions, and
forming at least one tunnel junction, the at least one tunnel junction located between juxtaposed sub-junctions of the plurality of sub-junctions.

18. The method according to claim 17, further including maintaining the photovoltaic device at a predetermined temperature to decrease the corresponding band gaps of the respective semiconductor material.

19. The method according to claim 18, wherein the predetermined temperature is selected to be greater than about 20° C. and less than about 150° C.

20. The method according to claim 17, wherein the forming of the plurality of sub-junctions includes forming each of the sub-junctions with a thickness less than a minority carrier diffusion for the semiconductor material of the corresponding solar cell.

21. The method according to claim 17, wherein each solar cell includes a first surface configured to receive radiation and a second surface to pass the received radiation,
wherein the forming of the plurality of sub-junctions includes forming the plurality of sub-junctions with increasing thickness from the first surface to the second surface.
